(19) United States
(12) Patent Application Publication
(10) Pub. No.: US 2025/0370352 A1
(43) Pub. Date: Dec. 4, 2025

(54) Methods And Systems For Measurement Of Semiconductor Structures With Mechanical Stress Modulation

(71) Applicant: KLA Corporation, Milpitas, CA (US)

(72) Inventor: Houssam Chouaib, Milpitas, CA (US)

(21) Appl. No.: 19/195,337

(22) Filed: Apr. 30, 2025

Related U.S. Application Data
(60) Provisional application No. 63/652,680, filed on May 29, 2024.

(51) Int. Cl. G03F 7/00; G01L 1/24

(52) U.S. Cl. CPC G03F 7/70655; G01L 1/241; G03F 7/70625; G03F 7/706841

(57) ABSTRACT

Methods and systems measuring structural parameters characterizing a measurement target based on changes in measurement signal values and estimated changes in electrical properties, optical properties, or both, of the measurement target due to variation of mechanical stress are presented herein. The electrical and optical properties of a measurement target are perturbed by inducing a mechanical wave within the measurement target under measurement. In preferred embodiments, the mechanical wave is excited by an ultrasonic actuator in contact with a back side of a wafer under measurement. Both the changes in the measurement signal values and estimated changes in the electrical, properties, optical properties, or both, of the measurement target are quantified and provided as input to a measurement model. In this manner, the measurement is based on the derivatives of measurement signals with respect to electrical properties, optical properties, or both.

### CROSS REFERENCE TO RELATED APPLICATION

The present application for patent claims priority under 35 U.S.C. § 119 from U.S. provisional patent application Ser. No. 63/652, 680, entitled “Piezo Modulation Scatterometry Apparatus,” filed May 29, 2024, the subject matter of which is incorporated herein by reference in its entirety.

### TECHNICAL FIELD

The described embodiments relate to metrology systems and methods, and more particularly to methods and systems for improved measurement accuracy.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology processes are used at various steps during a semiconductor manufacturing process to detect defects on wafers to promote higher yield. Optical and x-ray based metrology techniques offer the potential for high throughput without the risk of sample destruction. A number of techniques including scatterometry, ellipsometry, and reflectometry implementations and associated analysis algorithms are commonly used to characterize critical dimensions, film thicknesses, composition, overlay, and other parameters of nanoscale structures.

As devices (e.g., logic and memory devices) move toward smaller nanometer-scale dimensions, characterization becomes more difficult. Devices incorporating complex three-dimensional geometry and materials with diverse physical properties contribute to characterization difficulty. In some examples, semiconductor devices are increasingly valued based on their energy efficiency, rather than speed alone. For example, energy efficient consumer products are more valuable because they operate at lower temperatures and for longer periods of time on a fixed battery power supply. In another example, energy efficient data servers are in demand to reduce their operating costs. As a result, there is a strong interest to reduce the energy consumption of semiconductor devices. Solutions include the use of high-K material layers and complex geometric structures, both of which contribute to characterization difficulty.

Modern semiconductor processes are employed to produce complex structures. A complex measurement model with multiple parameters is required to represent these structures and account for process and dimensional variations. Complex, multiple parameter models include modeling errors induced by parameter correlations and low measurement sensitivity to some parameters. In addition, regression of complex, multiple parameter models having a relatively large number of floating parameter values may not be computationally tractable.

In some examples, a number of parameters are typically fixed in a model-based measurement to reduce the impact of these error sources and reduce computational effort. Although fixing the values of a number of parameters may improve calculation speed and reduce the impact of parameter correlations, it also leads to errors in the estimates of parameter values.

In some other examples, measurements are performed while the local environment around a metrology target under measurement is treated with a flow of purge gas that includes a controlled amount of fill material. A portion of the fill material condenses onto the structures under measurement and fills openings in the structural features, openings between structural features, etc. The presence of the fill material changes the optical properties of the structure under measurement compared to a measurement scenario where the purge gas is devoid of any fill material. Model based measurements are performed with an enriched data set including measurement signals collected from the metrology target having geometric features filled with fill material. This reduces parameter correlation among floating measurement parameters and improves measurement accuracy. In this manner, model-based measurement results can be obtained with reduced computational effort. Further details are described in U.S. Pat. No. 10,145,674 assigned to KLA-Tencor Corporation, Milpitas, California, the contents of which are incorporated herein by reference in their entirety. Unfortunately, applying a fill material to a wafer introduces problems with contamination of the wafer itself, limited contrast induced by the fill material, lack of flexibility in the selection of the fill material, increased system complexity, and increased risk due to contact with the wafer surface.

Other measurement examples include various forms of modulation spectroscopy, e.g., photo-modulated reflectivity and electroreflectance spectroscopy, in which periodic changes are induced in the electric field of the sample under test. The modulation of the electric field effectively causes a modulation of the dielectric function of the sample materials at the same frequency. The measured signal is typically expressed as the change in reflectivity, ΔR, divided by the nominal reflectivity, R. The measurement signal, ΔR/R, exhibits features associated with various electronic transitions in the sample materials. In one example, the measurement signal, ΔR/R, is highly sensitive to the band structure of the sample materials.

In some existing systems, reflectometry measurements are performed while modulating the intensity of a pump beam delivered to a measurement site. Measurements of light reflected or scattered from the sample in response to a probe beam are performed while the pump beam illuminates the measurement site. In some examples, the pump beam and the probe beam are the same beams. The modulated pump beam induces a change in the electric field in the sample, which in turn, modulates the reflectivity of the sample under measurement. In some of these examples, the line shape of the measured changes in reflectivity, e.g., ΔR/R, is examined directly to determined values of parameters of interest, e.g., band gap. In some other examples, a measurement model is employed to determine values of parameters of interest based on the measured changes in reflectivity, e.g., ΔR/R.

In existing systems, the induced changes in internal optical properties of the measurement target due to the modulated pump beam are not quantified and provided as input to a measurement model. Rather, measurement results are derived solely from changes in observed optical properties, e.g., reflectivity. This approach limits the range of parameters of interest that may be measured based on modulated reflectivity data.

Currently, the solution of complex, multiple parameter measurement models often requires an unsatisfactory compromise. Current model reduction techniques are sometimes unable to arrive at a measurement model that is both computationally tractable and sufficiently accurate. Moreover, complex, multiple parameter models make it difficult, or impossible, to optimize system parameter selections (e.g., wavelengths, angles of incidence, etc.) for each parameter of interest.

Future metrology applications present challenges due to increasingly small resolution requirements, multi-parameter correlation, increasingly complex geometric structures, and increasing use of opaque materials. Accordingly, it would be advantageous to develop high throughput systems and methods for characterizing complex semiconductor structures, e.g., structures incorporating high-k dielectric layers. In particular, it would be advantageous to develop a robust, reliable, and stable approach to in-line metrology of gate stacks including high-k dielectrics. Thus, methods and systems for improved measurements of semiconductor structures are desired.

### SUMMARY

Methods and systems measuring structural parameters characterizing a measurement target based on changes in measurement signal values and estimated changes in electrical properties, optical properties, or both, of the measurement target due to variation of mechanical stress are presented herein. The electrical and optical properties of a measurement target are perturbed by exciting a mechanical wave within the measurement target.

The perturbation of the electrical and optical properties of the measurement target induces changes in the measurement signal values. Both the changes in the measurement signal values and estimated changes in the electrical properties, optical properties, or both, of the measurement target are quantified and provided as input to a measurement model. In this manner, the measurement is based on the derivatives of measurement signals with respect to electrical properties, optical properties, or both. In some examples, measurements based on these derivative quantities enable increased sensitivity to film and CD parameters with reduced correlations among the parameters characterizing different materials comprising the structure under measurement.

The methods and systems described herein are applicable to a wide range of contactless and non-destructive measurement systems, e.g., optical, electron-based, and x-ray based measurement systems, operating in any number of signal modalities, e.g., reflectometry, ellipsometry, scatterometry, pupil imagery, field imagery, hyperspectral imagery, interferometry, etc.

A mechanical wave excitation source excites a mechanical wave propagating in a measurement target. In preferred embodiments, a mechanical wave excitation source is in contract with a back side of a wafer under measurement. In some other embodiments, a mechanical wave source generates a pressure wave directed to a top surface of a wafer under measurement.

In one aspect, the mechanical wave characteristics are selected to break correlations among different materials comprising the structure under measurement. In some examples, different material layers have very low optical contrast, but very different photo-elastic properties. In these examples, the differences in photo-elastic properties are exploited to generated measurement contrast between different material layers of a multi-layer stack.

In some examples, the changes in the electrical, properties, optical properties, or both, of the measurement target are estimated based on separate measurements of single layer film samples. The electrical properties, optical properties, or both, of each single layer film sample are measured with and without exciting a mechanical wave in the film sample at specified energy levels. The difference in measured properties is the induced change in electrical properties, optical properties, or both, associated with the specified energy levels. In some embodiments, the single layer film samples are located on the same wafer as the measurement target. In some other embodiments, the single layer film samples are located on other wafers.

The methods and systems described herein enable improved measurements of structural elements common in semiconductor manufacturing, e.g., material composition, alloy fraction measurements of compound semiconductors, material band gap, characterization of semiconductor surfaces and interfaces, film layer properties, critical dimensions, etc. Measurement applications include measurements of structural elements comprising complex semiconductor structures such as 3D VNAND structures and Gate-All-Around (GAA) structures, including front-end-of-line (FEOL) layers from oxide definition layers to high-k metal gate (HKMG) stacks. Measurement applications include measurements of structural elements comprised of semiconducting materials, insulating dielectric materials, and conducting materials, including organic materials, inorganic materials, or a combination thereof.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a diagram illustrative of a spectroscopic ellipsometry system configured to modulate the electrical and optical properties of a measurement target and measure structural parameters characterizing the measurement target based on changes in measurement signal values and estimated changes in optical properties of the measurement target induced by changes in mechanical stress.

FIG. 2 is a diagram illustrative of a mechanical wave excitation source in one embodiment.

FIG. 3 is a diagram illustrative of a mechanical wave excitation source in another embodiment.

FIG. 4 is a diagram illustrative of a mechanical wave excitation source in yet another embodiment.

FIG. 5 is a diagram illustrative of a mechanical wave excitation source in yet another embodiment.

FIG. 6 is a diagram illustrative of derivative based measurement engine 160 in one embodiment.

FIG. 7 is a diagram illustrative of a silicon nitride sample with a mechanical wave propagating through the sample.

FIG. 8 is a diagram illustrative of a multi-layer material stack disposed on a silicon substrate with a mechanical wave propagating through the multi-layer material stack.

FIG. 9 is a diagram illustrative of an illumination beam incident on a wafer at a particular orientation described by an angle of incidence, θ, and an azimuth angle, ϕ.

FIG. 10 is a flowchart illustrative of a method 200 for measuring structural parameters characterizing a measurement target based on changes in measurement signal values and estimated changes in optical properties of the measurement target induced by changes in mechanical stress as described herein.

### DETAILED DESCRIPTION

Reference will now be made in detail to background examples and some embodiments of the invention, examples of which are illustrated in the accompanying drawings.

Methods and systems for measuring structural parameters characterizing a measurement target subjected to changes in mechanical stress, or equivalently, mechanical strain, are presented herein. The measurement is based on changes in measurement signal values and estimated changes in electrical properties, optical properties, or both, of the measurement target induced by changes in mechanical stress, or equivalently, changes in mechanical strain.

In preferred embodiments, the changes in electrical and optical properties are induced by propagating a wave of mechanical energy through the measurement target. The mechanical wave propagation causes changes of both mechanical strain and mechanical stress within the solid. The relationship between the mechanical strain and stress within the solid is dictated by the specific mechanical properties of the solid material. For purposes of inducing changes in electrical and optical properties of a material via propagation of a wave of mechanical energy through a solid material, it is equivalent to refer to the mechanical wave propagating through the measurement target as a mechanical stress wave or a mechanical strain wave.

A propagating mechanical wave induces a periodic change in electrical and optical properties of the measurement target at the location of measurement. The perturbation of the electrical and optical properties of the measurement target induces changes in the measurement signal values. Both the changes in the measurement signal values and the electrical, properties, optical properties, or both, are quantified and provided as input to a measurement model. A measurement model estimates values of one or more parameters of interest characterizing one or more structural elements of the measurement target based on both the changes in measurement signal values and changes in the electrical properties, optical properties, or both.

In this manner, the measurement model operates on derivative information, i.e., changes in measurement signals as a function of changes in electrical properties, optical properties, or both, to estimate values of one or more parameters of interest. In some examples, measurements based on these derivative quantities enable increased sensitivity to film and CD parameters with reduced correlations among the parameters characterizing different materials comprising the structure under measurement.

The methods and systems described herein are applicable to a wide range of contactless and non-destructive measurement systems, e.g., optical, electron-based, and x-ray based measurement systems, operating in any number of signal modalities, e.g., reflectometry, ellipsometry, scatterometry, pupil imagery, field imagery, hyperspectral imagery, interferometry, etc. Model based measurements performed based on derivative information as described herein breaks correlations and provides sensitivity to structural parameters that would not otherwise be accessible by contactless and non-destructive measurement systems. Exemplary parameters of interest include, but are not limited to, critical dimensions, film thicknesses, overlay dimensions, optical properties of a material, electrical properties of a material, mechanical properties of a material, thermal properties of a material, etc.

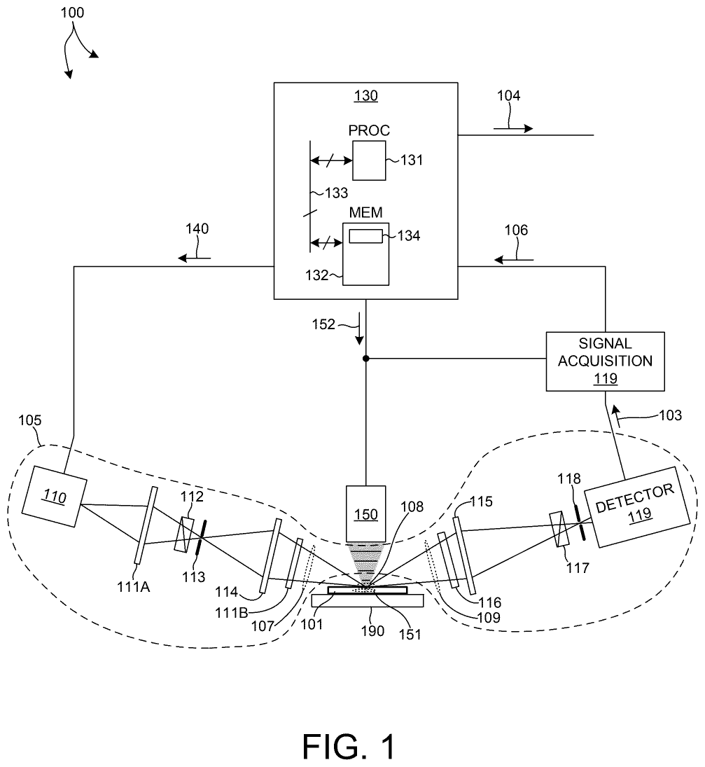

FIG. 1 is a diagram illustrative of a spectroscopic ellipsometry system configured to modulate the electrical and optical properties of a measurement target and measure structural parameters characterizing the measurement target based on changes in measurement signal values and estimated changes in optical properties of the measurement target induced by mechanical stress.

FIG. 1 depicts an exemplary spectroscopic ellipsometer (SE) metrology system 100 for performing derivative SE measurements of one or more metrology targets as described herein. As depicted in FIG. 1, metrology system 100 includes a SE subsystem 105 including an illumination source 110 that generates a beam of SE illumination light 107 incident on wafer 101. In some embodiments, illumination source 110 is a broadband illumination source that emits illumination light in the ultraviolet, visible, and infrared spectra. In one embodiment, illumination source 110 is a laser sustained plasma (LSP) light source (a.k.a., laser driven plasma source). The pump laser of the LSP light source may be continuous wave or pulsed. Illumination source 110 can be a single light source or a combination of a plurality of broadband or discrete wavelength light sources. The light generated by illumination source 110 includes a continuous spectrum or parts of a continuous spectrum, from ultraviolet to infrared (e.g., vacuum ultraviolet to mid infrared). In general, illumination light source 110 may include a super continuum laser source, an infrared helium-neon laser source, an arc lamp, a globar source, or any other suitable light source.

In some embodiments, the amount of SE illumination light is broadband illumination light that includes a range of wavelengths spanning at least 500 nanometers. In one example, the broadband SE illumination light includes wavelengths below 250 nanometers and wavelengths above 750 nanometers. In general, the broadband SE illumination light includes wavelengths between 120 nanometers and 4,200 nanometers. In some embodiments, broadband illumination light including wavelengths beyond 4,200 nanometers, e.g., mid-infrared and far-infrared wavelengths, may be employed. In some embodiments, illumination source 110 includes a deuterium source emitting light with wavelengths across a range from 150 nanometers to 400 nanometers, a LSP source emitting light with wavelengths across a range from 180 nanometers to 2,500 nanometers, a supercontinuum source emitting light with wavelengths across a range from 400 nanometers to 4,200 nanometers, and a globar source emitting light with wavelengths across a range from 2,000 nanometers to 20,000 nanometers.

As depicted in FIG. 1, SE subsystem 105 includes an SE illumination subsystem configured to direct SE illumination light 107 to one or more structures formed on the wafer 101. The SE illumination subsystem is shown to include light source 110, illumination optics 111A, one or more optical filters 111B, polarizing component 112, illumination field stop 113, and illumination pupil aperture stop 114. As depicted, in FIG. 1, the beam of SE illumination light 107 passes through illumination optics 111A, optical filter(s) 111B, polarizing component 112, field stop 113, and aperture stop 114 as the beam propagates from the illumination source 110 to wafer 101. SE illumination light 107 illuminates a portion of wafer 101 over a measurement spot 108.

The illumination optics 111A conditions illumination light 107 and focuses SE illumination light 107 on measurement spot 108. The one or more optical filters 111B are used to control light level, spectral output, or combinations thereof, from the illumination subsystem. In some examples, one or more multi-zone filters are employed as optical filters 111B. Polarizing component 112 generates the desired polarization state exiting the illumination subsystem. In some embodiments, the polarizing component is a polarizer, a compensator, or both, and may include any suitable commercially available polarizing component. The polarizing component can be fixed, rotatable to different fixed positions, or continuously rotating. Although the SE illumination subsystem depicted in FIG. 1 includes one polarizing component, the SE illumination subsystem may include more than one polarizing component. Field stop 113 controls the field of view (FOV) of the SE illumination subsystem and may include any suitable commercially available field stop. Aperture stop 114 controls the numerical aperture (NA) of the SE illumination subsystem and may include any suitable commercially available aperture stop. The SE illumination subsystem may include any type and arrangement of illumination optics 111A, optical filter(s) 111B, polarizing component 112, field stop 113, and aperture stop 114 known in the art of spectroscopic ellipsometry.

Metrology system 100 also includes a collection optics subsystem configured to collect light generated by the interaction between the one or more structures and the incident SE illumination light 107. A beam of collected light 109 is collected from measurement spot 108 by collection optics 115. Collected light 109 passes through collection aperture stop 116, polarizing element 117, and field stop 118 of the collection optics subsystem.

Collection optics 115 includes any suitable optical elements to collect light from the one or more structures formed on wafer 101. Collection aperture stop 116 controls the NA of the collection optics subsystem. Polarizing element 117 analyzes the desired polarization state. The polarizing element 117 is a polarizer or a compensator. The polarizing element 117 can be fixed, rotatable to different fixed positions, or continuously rotating. Although the collection subsystem depicted in FIG. 1 includes one polarizing element, the collection subsystem may include more than one polarizing element. Collection field stop 118 controls the FOV of the collection subsystem. The collection subsystem takes light from wafer 101 and directs the light through collection optics 115, aperture stop 116, and polarizing element 117 to be focused on collection field stop 118. In some embodiments, collection field stop 118 is used as a spectrometer slit for the spectrometers of the detection subsystem. However, collection field stop 118 may be located at or near a separate spectrometer slit of the spectrometers of the detection subsystem. The collection subsystem may include any type and arrangement of collection optics 115, aperture stop 116, polarizing element 117, and field stop 118 known in the art of spectroscopic ellipsometry.

As depicted in FIG. 1, SE metrology system 100 includes a mechanical wave excitation source 150 that excites a mechanical wave in wafer 101 at measurement spot 108. The mechanical wave is coincident with the SE illumination light 107 projected onto the surface of a wafer under measurement over an area that includes at least a portion of measurement spot 108. In some examples, the area of incidence of the mechanical wave at the surface of the sample partially overlaps measurement spot 108. In some other examples, the area of incidence of the mechanical wave at the surface of the sample completely overlaps measurement spot 108. In some of these embodiments, the area of incidence of the mechanical wave at the surface of the sample is larger than measurement spot 108, and completely overlaps measurement spot 108. In this manner, the optical properties of the structures measured by SE illumination light 107 are modulated by the mechanical stress wave at measurement spot 108. As depicted in FIG. 1, command signal 152 is communicated to mechanical wave excitation source 150. Command signal 152 includes parameters required to characterize the desired mechanical wave. By way of non-limiting example, command signal 152 includes the desired energy of the mechanical wave, the desired modulation frequency of the mechanical wave, the desired waveform of the mechanical wave, the desired spot size of the mechanical wave at the surface of the sample, etc. In response, mechanical wave excitation source 150 induces a mechanical wave in accordance with the desired characteristics specified by command signal 152.

In some examples, the ratio of mechanical wave excitation intensity and illumination beam intensity is optimized for specific film stacks or structures under measurement.

In general, the mechanical wave induced in wafer 101 at measurement spot 108 may vary between different energy levels in any periodic or non-periodic manner. In some examples, the mechanical wave is varied in a binary manner, e.g., on/off, in accordance with a sinusoid between different energy levels, in accordance with a square wave between different energy levels, etc. In this manner, the reflectance, transmission, or polarization of the measured structure alternates between the signal values in the absence of perturbation of the optical properties and the signal values in the presence of a perturbation of the optical properties of the structure under measurement due to a mechanical stress wave.

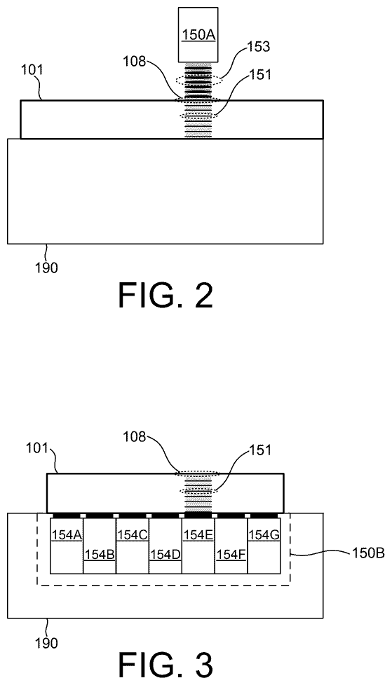

FIG. 2 is a diagram illustrative of a mechanical wave excitation source in one embodiment. In the embodiment depicted in FIG. 2, mechanical wave excitation source 150A is a Lorentz coil actuator that generates a pressure wave 153 incident on wafer 101. The pressure wave 153 propagates through the gaseous environment surrounding wafer 101, e.g., clean, dry air, nitrogen purge environment, etc. The interaction between the incident pressure wave 153 and wafer 101 excites a mechanical wave 151 in the sample. The amplitude of the pressure wave, the frequency of the pressure wave, the waveform of the pressure wave, or any combination thereof, are controlled to achieve a desired mechanical wave 151 in the semiconductor material. By way of non-limiting example, the waveform of a pressure wave is selected to be a sinusoidal wave, a square wave, a pulse wave, etc. As illustrated in FIG. 2, the mechanical wave excitation source 150A is not in contact with wafer 101, and thus does not pose a risk of damaging the structures fabricated on the top surface of wafer 101.

FIG. 3 is a diagram illustrative of a mechanical wave excitation source in another embodiment. In the embodiment depicted in FIG. 3, mechanical wave excitation source 150B is an array of actuators 154A-G mounted to wafer chuck 190. In preferred embodiments, the actuators are ultrasonic transducers. Ultrasonic transducers are able to sustain a mechanical wave within wafer 101 having desired waveform characteristics selected from a wide range of waveform shapes, energy levels, and frequencies because the ultrasonic transducer effectively sustains the mechanical wave 151. For example, the amplitude of the mechanical wave, the frequency of the mechanical wave, the waveform of the mechanical wave, or any combination thereof, can be controlled to achieve a desired mechanical wave in the semiconductor material. By way of non-limiting example, the waveform of a mechanical wave is selected to be a sinusoidal wave, a square wave, a pulse wave, etc.

In some other embodiments, the actuators are impact actuators, e.g., a solenoid actuator. Impact actuators are able to impart a mechanical pulse at the backside surface of wafer 101, which initiates, rather than sustains, mechanical wave propagation through wafer 101. In these embodiments, the characteristics of the mechanical wave 101 propagating through wafer 101 are dictated by the structure of wafer 101 as a mechanical pulse includes a wide range of frequencies, most of which decay quickly in wafer 101, while mechanical waves associated with one or more structural modes of wafer 101 will persist for longer periods of time.

As depicted in FIG. 3, the actuated portion of each of the actuators is in contact with the backside of wafer 101 when wafer 101 is chucked down onto the surface of wafer chuck 190. Each actuator generates a mechanical wave 151 that propagates directly in wafer 101 due to the contact between each actuator and the backside of wafer 101. For embodiments employing ultrasonic transducers, the amplitude of the mechanical wave, the frequency of the mechanical wave, the waveform of the mechanical wave, the incident spot size of the mechanical wave, location of incidence of the mechanical wave, or any combination thereof, are directly controlled to achieve a desired mechanical wave 151 in the semiconductor material. By way of non-limiting example, the waveform of a mechanical wave 151 is selected to be a sinusoidal wave, a square wave, a pulse wave, etc. As illustrated in FIG. 3, the mechanical wave excitation source 150B is not in contact with the top surface of wafer 101, and thus does not pose a risk of damaging the structures fabricated on the top surface of wafer 101. In general, the number of actuators is selected to enable mechanical wave propagation at any location of measurement spot 108 on wafer 101.

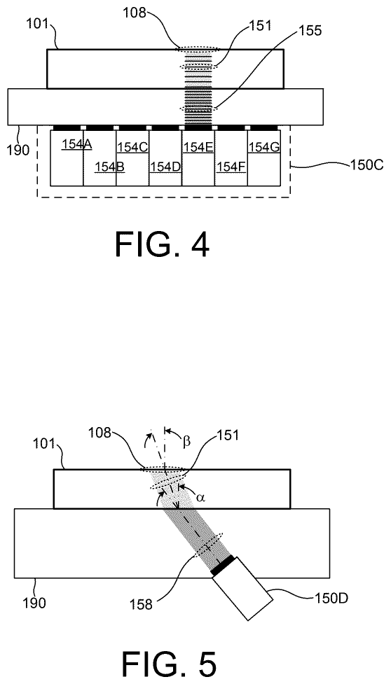

FIG. 4 is a diagram illustrative of a mechanical wave excitation source in another embodiment. In the embodiment depicted in FIG. 4, mechanical wave excitation source 150C is an array of actuators 154A-G mounted to wafer chuck 190 as described with reference to FIG. 3. However, in the embodiment depicted in FIG. 4, the actuated portion of each of the actuators is in contact with at the structure of wafer chuck 190, which, in turn, is in contact with the backside of wafer 101 when wafer 101 is chucked down onto the surface of wafer chuck 190. Each actuator generates a mechanical wave 155 that propagates through wafer chuck 190 and into wafer 101 as mechanical wave 151. The mechanical characteristics at the interface of wafer chuck 190 and wafer 101 change the waveform characteristics of mechanical wave 155 as it propagates into wafer 101. Thus, the waveform characteristics of mechanical waves 151 and 155 are different.

FIG. 5 is a diagram illustrative of a mechanical wave excitation source in another embodiment. In the embodiment depicted in FIG. 5, a mechanical wave excitation source includes an actuator 150D mounted to wafer chuck 190 as described with reference to FIG. 4. However, in the embodiment depicted in FIG. 5, mechanical wave 151 propagates through wafer 101 at an angle, β, with respect to a normal to the surface of wafer 101. In the embodiment depicted in FIG. 5, the actuated portion of each of the actuators is in contact with at the structure of wafer chuck 190 at an angle, α, with respect to the surface normal at the interface between wafer chuck 190 and wafer 101. As depicted in FIG. 5, actuator 150D generates a mechanical wave 158 that propagates through wafer chuck 190 at an angle, α, and into wafer 101 as mechanical wave 151, at an angle, b, with respect to the surface normal at the interface between wafer chuck 190 and wafer 101. The different mechanical characteristics of the materials comprising wafer chuck 190 and wafer 101 change the angle of propagation of mechanical wave 155 as it propagates across the interface between wafer chuck 190 and wafer 101.

In the embodiment depicted in FIG. 1, the collection optics subsystem directs light to detector 119. Detector 119 generates output responsive to light collected from the one or more structures illuminated by the SE illumination subsystem at measurement spot 108. In one example, detector 119 includes charge coupled devices (CCD) sensitive to ultraviolet and visible light (e.g., light having wavelengths between 190 nanometers and 860 nanometers). In other examples, detector 119 includes a photo detector array (PDA) sensitive to infrared light (e.g., light having wavelengths between 950 nanometers and 2500 nanometers). However, in general, detector 119 may include other detector technologies and arrangements (e.g., a position sensitive detector (PSD), an infrared detector, a photovoltaic detector, a quadrature cell detector, a camera, etc.). Each detector converts the incident light into electrical signals indicative of the spectral intensity of the incident light. In general, detector 119 generates SE measurement signals 103 indicative of the light detected on detector 119.

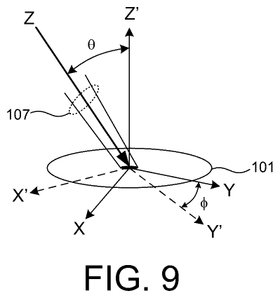

Each orientation of the SE illumination beam 107 relative to the surface normal of semiconductor wafer 101 is described by any two angular rotations of wafer 101 with respect to the illumination beam 107, or vice-versa. In one example, the orientation can be described with respect to a coordinate system fixed to the wafer. FIG. 9 depicts SE illumination beam 107 incident on wafer 101 at a particular orientation described by an angle of incidence, θ, and an azimuth angle, ϕ. Coordinate frame XYZ is fixed to the SE metrology system (e.g., SE illumination beam 107) and coordinate frame X′Y′Z′ is fixed to wafer 101. The Y axis is aligned in plane with the surface of wafer 101. X and Z are not aligned with the surface of wafer 101. Z′ is aligned with an axis normal to the surface of wafer 101, and X′ and Y′ are in a plane aligned with the surface of wafer 101. As depicted in FIG. 9, SE illumination beam 107 is aligned with the Z-axis and thus lies within the XZ plane. Angle of incidence, θ, describes the orientation of the SE illumination beam 107 with respect to the surface normal of the wafer in the XZ plane. Furthermore, azimuth angle, ϕ, describes the orientation of the XZ plane with respect to the X′Z′ plane. Together, θ and ϕ, uniquely define the orientation of the SE illumination beam 107 with respect to the surface of wafer 101. In this example, the orientation of the SE illumination beam with respect to the surface of wafer 101 is described by a rotation about an axis normal to the surface of wafer 101 (i.e., Z′ axis) and a rotation about an axis aligned with the surface of wafer 101 (i.e., Y axis).

As illustrated in FIG. 1, SE metrology tool 100 includes a specimen positioning system 190 configured to both align specimen 101 and orient specimen 101 over a large range of angles of incidence and azimuth angle with respect the illumination beam 107. In this manner, measurements of specimen 101 are collected by metrology system 100 over any number of locations and orientations on the surface of specimen 101. In one example, computing system 130 communicates command signals (not shown) to specimen positioning system 190 that indicate the desired position of specimen 101. In response, specimen positioning system 190 generates command signals to the various actuators of specimen positioning system 190 to achieve the desired positioning of specimen 101.

In general, specimen positioning system 190 may include any suitable combination of mechanical elements to achieve the desired linear and angular positioning performance, including, but not limited to goniometer stages, hexapod stages, angular stages, and linear stages.

In general, an optical scatterometer, such as SE metrology system 100 is configured to deliver illumination light to a metrology target under measurement at any desired angle of incidence and azimuth angle.

The optical properties of the structures subjected to variations in mechanical stress are modulated at the same frequency as the variations in mechanical stress. To capture the induced changes in the SE measurement signals, the spectra must be collected quickly, i.e., at a frequency at least twice the frequency of the highest frequency mechanical wave to avoid losing signal information. Moreover, the modulated SE measurement signal, ΔSE, is relatively small compared to the unmodulated SE measurement signal, SE. Thus, the SE measurement signal may be dominated by optical and electrical noise. Fortunately, the modulated SE signal 106 is present at a known frequency and may be detected using any suitable lock-in detection scheme. In some embodiments, signal acquisition electronics 119 implements lock-in detection based on the modulation frequency dictated by command signal 152. Lock-in detection detects the portion of the signal at the known modulation frequency or set of frequencies and discriminates against portions of the signal at other frequencies. Phase-sensitive detection and lock-in amplification are common signal extraction techniques that may be employed to recover the modulated SE measurement signal from the detected measurement signals 103.

Extraction of the modulated SE measurement signal 106 using phase-sensitive lock-in amplification, for example, requires at least one measurement at each wavelength over a time interval including an instance when the mechanical stress is present and an instance when mechanical stress is not present. Serial detection at each wavelength with a lock-in amplifier leads to long measurement times because the measurements over the desired range of wavelengths are performed sequentially over time.

In some embodiments, signal multiplexing is employed to measure multiple wavelengths simultaneously to reduce signal acquisition time. During each period of the modulation, the detection system simultaneously measures each dispersed beam with a multiplexed readout of signals from the detectors. Furthermore, the detection system calculates the modulated SE signal from the signals at each wavelength.

Collected light is spatially dispersed across a detector array according to wavelength. Light from each narrow band of wavelengths is incident on a different pixel of the detector array. The detected light signal at each narrow band of wavelengths is measured simultaneously by a multiplexed readout of the pixels.

The electronics subsystem of the detector reads the modulated SE signal as well as the unmodulated SE signal from each pixel of the detector array in rapid succession. Multiple measurements of the modulated signal are made within a single period of the modulation cycle. In this manner, the detector enables simultaneous measurement of the SE measurement signal at all desired wavelengths in parallel.

In general, the detected SE measurement signals depend on the configuration of the SE subsystem. In some embodiments, the detected SE measurement signals are SE harmonic signals, e.g., {α,β}, {ψ,Δ}, etc. In some embodiments the detected SE measurement signals are one or more elements of the Mueller Matrix representation of the SE measurement. In general, any detected SE measurement signal sensitive to changes in optical properties due to mechanical stress may be contemplated within the scope of this patent document.

Metrology system 100 also includes computing system 130 configured as a derivative based measurement engine 160 configured to estimate values of one or more parameters of interest 104 characterizing a structure under measurement based on changes in measurement signal values and estimated changes in optical properties of the structure induced by modulation of the electrical and optical properties of the structure.

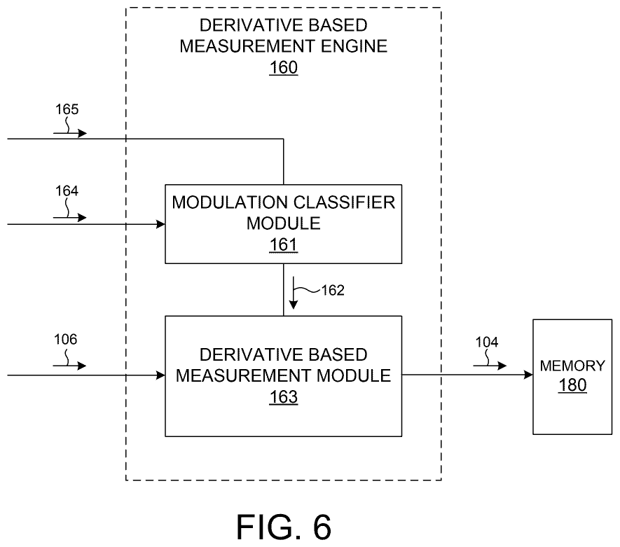

FIG. 6 is a diagram illustrative of derivative based measurement engine 160 in one embodiment. As depicted in FIG. 6, derivative based measurement engine 160 includes a modulation classifier module 161 and a derivative based measurement module 163. A signal 165 indicative of the properties of the mechanical wave 151 propagating in wafer 101 at measurement spot 108 is communicated to modulation classifier 161. In one example, signal 165 is the command signal 152 communicated to mechanical wave excitation source 150 depicted in FIG. 1. In one example, signal 165 includes the commanded waveform, amplitude, and frequency of a mechanical wave generated by the mechanical wave excitation source 150. In addition, a signal 164 indicative of the materials comprising the structure under measurement is communicated to modulation classifier module 161.

In response to signals 164 and 165, modulation classifier module 161 generates a signal 162 indicative of the induced changes in optical properties of the structure under measurement, e.g., {Δnₓ, Δn_{y}, Δkₓ, Δk_{y}}, due to the mechanical wave 151 propagating within the structure under measurement. In some examples, modulation classifier module 161 includes a library database characterizing the changes in optical properties of various materials employed in semiconductor manufacturing induced by mechanical stress waves at different energy levels. In some other examples, modulation classifier module 161 includes a model characterizing the changes in optical properties of various materials employed in semiconductor manufacturing induced by wave propagation at different energy levels.

The changes in optical properties of semiconductor materials are expected to be independent of geometry. In some examples, single layer film samples are prepared each including a layer of each different material. The variation in optical properties, e.g., {Δnₓ, Δn_{y}, Δkₓ, Δk_{y}}, are measured using conventional SE measurements during mechanical wave propagation at a number of different energy levels. The difference between the measured optical properties at peak mechanical stress and the measured optical properties at zero mechanical stress is the induced change in optical properties, e.g., {Δnₓ, Δn_{y}, Δkₓ, Δk_{y}}, at each of the specified energy levels. In some embodiments, these calibrated values are entered into a database and interpolated to specify the induced change in optical properties for any specified mechanical wave energy level. In these embodiments, modulation classifier module 161 includes the database. In some other embodiments, the calibrated values are fit to a model that specifies the induced change in optical properties for any specified mechanical wave energy level. In these embodiments, modulation classifier module 161 includes the trained model.

In some examples, one or more metrology targets are disposed at a different location on the same semiconductor wafer as the structure under measurement. Each metrology target includes a single film layer corresponding to each of the different materials comprising the structure under measurement. The change in value of the one or more electrical or optical properties of each metrology target induced by the mechanical wave is measured. The variation of energy of the mechanical wave employed to measure each single film layer metrology target is the same as the variation of energy of the mechanical wave employed to measure the structure under measurement. In this manner, the measured change in value of the one or more electrical or optical properties of each metrology target is directly applicable to the model based measurement of the structure under measurement.

As depicted in FIG. 6, signal 162 indicative of the values of the induced changes in optical properties of the structure under measurement, e.g., {Δnₓ, Δn_{y}, Δkₓ, Δk_{y}}, is communicated to derivative based measurement module 162. In one example, signal 162 includes two vectors. One vector expresses the difference between the induced changes in the in-plane indices of refraction, {Δnₓ−Δn_{y}}, as a function of wavelength, and the other vector expresses the difference between the induced changes in the in-plane absorption coefficients, {Δkₓ−Δk_{y}}, as a function of wavelength. In addition, SE measurement signals 106 are communicated to derivative based measurement module 163. The SE measurement signals vary due to the perturbation of the optical properties of the structure under measurement induced by the mechanical wave 151. In some examples, the SE measurement signals include one or more elements of the Mueller Matrix. In these examples, the changes in value of the one or more elements of the Mueller Matrix induced by the modulation are provided as input to the measurement model. In some examples, the SE measurement signals are the harmonic signals generated by the spectrometer. In these examples, the changes in value of the harmonic signals induced by the modulation are provided as input to the measurement model.

Derivative based measurement module 163 includes a derivative based model that estimates values of one or more parameters of interest characterizing the structure under measurement based on the changes in SE measurement signals and the values of the induced changes in optical properties of the structure under measurement, e.g., {Δnₓ, Δn_{y}, Δkₓ, Δk_{y}}.

In some embodiments, the derivative based measurement model is a trained, machine-learning (ML) based model. The ML based model is trained using Design Of Experiments (DOE) data sets associated with DOE measurement targets having known values of the parameters of interest. The DOE data sets include changes in SE measurement signals and the values of the induced changes in optical properties of the structure under measurement, e.g., {Δnₓ, Δn_{y}, Δkₓ, Δk_{y}}, associated with DOE measurements of the DOE measurement targets. In some examples, the DOE measurements are actual SE measurements of DOE measurement targets having known values of parameters of interest. In some of these examples, the known values of the parameters of interest are obtained by measurement using a trusted reference metrology system. In some other examples, the DOE measurements are simulated SE measurements of simulated DOE measurement targets having programmed values of the parameters of interest.

In some embodiments, the derivative based measurement model is a physics based model that relates the values of the induced changes in optical properties of the structure under measurement, e.g., {Δnₓ, Δn_{y}, Δkₓ, Δk_{y}} and assumed values of parameters of interest to predicted normalized changes in SE measurement signals, e.g., (ΔSE/SE)*. The assumed values of the parameters of interest are updated as part of regression process until a sufficiently good fit is obtained between the predicted normalized changes in the SE measurement signals and the actual normalized changes in the SE measurement signals, e.g., (ΔSE/SE). When a sufficiently good fit is obtained, the estimated values of the parameters of interest 104 are communicated to a memory, e.g., memory 180.

The normalized changes in the SE measurement signals 106 define the change in any spectroscopic ellipsometry signal as illustrated in Equation (1), where SE_{ON} are the SE measurement signal values when the power of pump illumination light 151 is maximal, and SE_{OFF} are the SE measurement signal values when the power of pump illumination light 151 is minimal, e.g., zero.

$$\frac{Δ SE}{SE} = \frac{{SE}_{ON} - {SE}_{Off}}{{SE}_{Off}} \qquad ( 1 )$$

As described hereinbefore, the SE signals include any suitable SE signal generated by a spectrometer of the SE measurement system, e.g., harmonic signals, one or more Mueller Matrix elements, etc.

In one example, spectroscopic ellipsometry measurements of structures undergoing periodic mechanical stress yields conventional ellipsometric signals, Ψ and Δ, defined as the ratio of the complex Fresnel coefficients, rₚ and rₛ as illustrated in Equation (2), where tanΨ is illustrated by Equation (3).

$$ρ = \frac{{r}_{p}}{{r}_{s}} = tan Ψ {e}^{i Δ} \qquad ( 2 )$$

$$tan Ψ = \vert \frac{{r}_{p}}{{r}_{s}} \vert \qquad ( 3 )$$

In response to mechanical stress, the optical properties of the sample will change. This is, in turn, changes the values of the ellipsometric parameters, Ψ and Δ. Ψ₀ and Δ₀ are the unperturbed values of ellipsometric signals, Ψ and Δ, and δΨ and δΔ correspond to the change in values of ellipsometric signals, Ψ and Δ, while the structure under measurement is under mechanical stress. In this example, the ellipsometric signals, Ψ and Δ, are described by Equations (4) and (5).

$$Ψ = {Ψ}_{0} + δΨ \qquad ( 4 )$$

$$Δ = {Δ}_{0} + δ Δ \qquad ( 5 )$$

Typically, the magnitude of change of the values of the ellipsometric signals is very small compared to the nominal values. In general, the magnitude of the change in values is periodic, e.g., sinusoidal in a steady-state vibration. Thus, the modulated part of equations (4) and (4) are the root mean squared amplitude of the sinusoidal or periodic time function. For small changes in values, Equations (6)-(9) are valid.

$$cos ( Δ ) = cos ( {Δ}_{0} ) - δ Δ sin ( Δ ) \qquad ( 6 )$$

$$sin ( Δ ) = sin ( {Δ}_{0} ) + δ Δ cos ( Δ ) \qquad ( 7 )$$

$$cos ( Ψ ) = cos ( {Ψ}_{0} ) - δ Ψ sin ( {Ψ}_{0} ) \qquad ( 8 )$$

$$tan ( Ψ ) = tan ( {Ψ}_{0} ) + δ Ψ {sec}^{2} ( Ψ ) \qquad ( 9 )$$

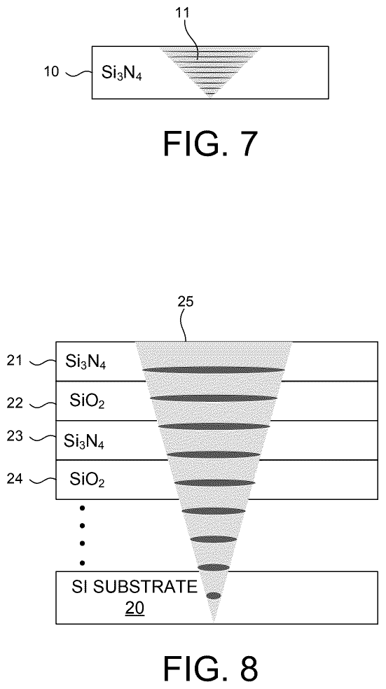

FIG. 7 is a diagram illustrative of a silicon nitride sample 10 with a mechanical wave 11 propagating through the sample, e.g., a mechanical stress wave. Mechanical stress wave 11, in turn, induces changes the optical properties of the material, e.g., refractive index, n, and absorption coefficient, k.

Most semiconductor materials exhibit stress-induced birefringence. In other words, an applied mechanical stress results in a polarization sensitive optical response. This response is observed because the in-plane refraction indexes, nₓ and n_{y}, are different when the material sample is under mechanical stress as illustrated in Equation (10).

$$Δ n ( λ ) = {n}_{x} ( λ ) - {n}_{y} ( λ ) \qquad ( 10 )$$

As illustrated by Equations (11)-(13), in general, the in-plane and out of plane refraction indexes shift relative to the nominal refraction index of the unstressed material, n₀, by different amounts when subjected to mechanical stress.

$${n}_{x} ( λ ) = {n}_{0} ( λ ) + Δ {n}_{x} ( λ ) \qquad ( 11 )$$

$${n}_{y} ( λ ) = {n}_{0} ( λ ) + Δ {n}_{y} ( λ ) \qquad ( 12 )$$

$${n}_{z} ( λ ) = {n}_{0} ( λ ) + Δ {n}_{z} ( λ ) \qquad ( 13 )$$

For a given isotropic material having thickness, t, the optical response of the material in a state of mechanical stress induces a phase change relative to the optical response of the material in a zero stress state as illustrated by Equations (14)-(16).

$${φ}_{x} ( λ ) = t Δ {n}_{x} ( λ ) \qquad ( 14 )$$

$${φ}_{y} ( λ ) = t Δ {n}_{y} ( λ ) \qquad ( 15 )$$

$${φ}_{z} ( λ ) = t Δ {n}_{z} ( λ ) \qquad ( 16 )$$

For many semiconductor materials, stress-induced birefringence results in a phase change in the x-y plane illustrated by Equation (17).

$${φ}_{xy} ( λ ) = t ( Δ {n}_{x} ( λ ) - Δ {n}_{y} ( λ ) ) \qquad ( 17 )$$

In some examples, the change in value of the refractive index in the x and y directions is significant and measurements performed at zero stress conditions and finite stress conditions results in two different measured signals. The difference between the two different measured signals provides derivative information, i.e., changes in measurement signals as a function of changes in optical properties.

A stress-optical coefficient associated with an isotropic material exhibiting stress-induced birefringence is illustrated by Equation (18), where σₓ and σ_{y} is the mechanical stress in the x and y directions, respectively.

$$C ( λ ) = \frac{( Δ {n}_{x} ( λ ) - Δ {n}_{y} ( λ ) )}{( Δ {σ}_{x} - Δ {σ}_{y} )} \qquad ( 18 )$$

As illustrated by Equation (18), the stress-optical coefficient, C, depends on the material properties and changes as a function of wavelength. Thus, the application of the same mechanical stress to a film stack results in a different optical response from each material layer and additional, unique measurement signals.

In some examples, an optical spectroscopy technique, e.g., reflectometry or ellipsometry, is employed to determine the induced mechanical stress in a known material. For example, for a known material, the stress-optical coefficients are known, and the induced changes in the dielectric function, e.g., measured changes in the optical dispersion parameters, n and k, for a single layer sample are measured by an optical spectroscopy technique. In these examples, Equation (18) may be employed to determine the induced changes in mechanical stress, Δσₓ−Δσ_{y}, from the known stress-optical coefficients, C(λ), and the measured changes in dispersion parameters, Δnₓ(λ)−Δn_{y}(λ). These results may be employed to calibrate a mechanical wave excitation source to generate a mechanical wave in a specimen that induces known mechanical stress conditions.

In general, many materials of interest employed in semiconductor device fabrication exhibit anisotropic photo-elastic properties due to their lattice structure. Moreover, the literature offers exemplary models describing the photo-elastic behavior of materials of interest employed in semiconductor fabrication. Some of these models are parameterized by one or more stress-optical parameters and the values of these parameters may be determined by measurements of samples of known materials under known mechanical stress conditions.

In general, the properties of the mechanical wave can be controlled by controlling the frequency and intensity of the excitation source. In one aspect, the mechanical wave energy, i.e., wavelength and amplitude, of the mechanical wave is selected to break correlations among different materials comprising the structure under measurement. In preferred embodiments, an excitation source generates a mechanical wave having desired mechanical wave energy within a measurement target.

In many materials employed in semiconductor manufacturing, the optical properties of the material, e.g., refractive index, n, and absorption coefficient, k, depend on the mechanical stress-strain state of the material, i.e., state of mechanical stress or strain. Moreover, the induced change in optical properties in response to a change in mechanical stress-strain state is different for different materials. Thus, different materials respond differently to the same mechanical wave propagating through the different materials. In this manner, differences in photo-elastic properties of different materials increases measurement signal diversity that helps to break correlations and enhance measurement sensitivity.

Traditionally, there are many semiconductor structures that incorporate different material layers that are very similar optically in a static mechanical stress-strain state. These material combinations exhibit low optical contrast and are difficult to measure. One example is a stack of alternating layers of Silicon Oxide (SiO₂) and Silicon Nitride (Si₃N₄). These materials exhibit very low optical contrast in a static state of mechanical stress-strain. However, the optical response of these materials to variations in mechanical stress-strain is very different. Thus, by subjecting the structures under measurement to a dynamically changing mechanical stress state, the optical response of the different materials is very different. In this manner, the same material combinations subjected to a dynamically changing mechanical stress state exhibit high optical contrast.

In some examples, stress modulation based measurements of multi-layer stacks of different material layers are performed. In some of these examples, the different material layers have very low optical contrast, but significant contrast in photo-elastic properties. In these examples, the mechanical wave energy is selected to exploit the contrast in photo-elastic properties of two different material layers of a multi-layer stack.

FIG. 8 is a diagram illustrative of a multi-layer material stack disposed on a silicon substrate with a mechanical wave propagating through the sample. As depicted in FIG. 8, a multi-layer material stack includes alternating layers 22 and 24 of silicon oxide (SiO₂) and layers 21 and 23 of silicon nitride (Si₃N₄) disposed on a silicon substrate 20. This type of thin film stack is commonly referred to as an Oxide/Nitride/Oxide (ONO) film stack. In some embodiments, each of the silicon nitride and silicon oxide layers are very thin, e.g., each layer has a thickness of approximately five nanometers. The optical properties of SiO₂ and Si₃N₄ are very similar and this leads to high correlation among the thickness, profile, and CD parameters characterizing stacked structures fabricated using both materials when optical based measurement tools are employed.

Although the optical contrast between SiO2 and Si3N4 layers is very low, the photo-elastic contrast between the two materials is significant, i.e., the change in optical properties in response to changes in mechanical stress is different. In this example, the difference between measured signals both with and without mechanical stress provides derivative information, i.e., changes in measurement signals as a function of changes in optical properties. In general, a wide number of derivative spectra can be generated by varying the mechanical wave amplitude, frequency, or both.

In general, the SE metrology system described with reference to FIG. 1 may be any form of a spectroscopic ellipsometer including, but not limited to, a rotating compensator SE system, a rotating polarizer SE system, a rotating polarizer, rotating compensator SE system, a rotating compensator, rotating compensator SE system, etc. In addition, the derivative based measurement techniques may be applied to other ellipsometric systems that employ non-rotating, solid state devices such as photo-elastic modulators to measure all or a portion of the sample Mueller matrix.

In general, the electrical properties of a measurement target are perturbed by inducing changes mechanical stress within the measurement target under measurement, which, in turn, changes the optical properties of the measurement target. As described hereinbefore, the changes in mechanical stress are induced by propagating a mechanical wave through the measurement target under measurement. However, in general, any suitable technique for changing the mechanical stress is contemplated within the scope of this patent document.

The methods and systems described herein enable improved measurements of structural elements common in semiconductor manufacturing, e.g., material composition, alloy fraction measurements of compound semiconductors, material band gap, characterization of semiconductor surfaces and interfaces, film layer properties, critical dimensions, etc. Measurement applications include measurements of structural elements comprising complex semiconductor structures such as 3D VNAND structures and Gate-All-Around (GAA) structures, including front-end-of-line (FEOL) layers from oxide definition layers to high-k metal gate (HKMG) stacks. Measurement applications include measurements of structural elements comprised of semiconducting materials, insulating dielectric materials, and conducting materials, including organic materials, inorganic materials, or a combination thereof.

In general, the modulation frequency and amplitude of the mechanical wave are selected for each measurement application to improve sensitivity and reduce correlations.

In general, the techniques to break correlations among various contributors to the measured optical response described herein may be combined to improve the accuracy of measurements of complex semiconductor structures. For example, derivative based measurements of structures at various wavelengths, angles of incidence, azimuth angles, or any combination thereof can be analyzed sequentially or in parallel to accurately decorrelate structural features associated with complex multi-layer structures.

In a further aspect, the wavelengths emitted by the measurement illumination source, e.g., illumination source 110, are selectable. In some embodiments, illumination source 110 is a LSP light source controlled by computing system 130 to maximize flux in one or more selected spectral regions. Laser peak intensity at the target material controls the plasma temperature and thus the spectral region of emitted radiation. Laser peak intensity is varied by adjusting pulse energy, pulse width, or both. As depicted in FIG. 1, computing system 130 communicates command signal 140 to illumination source 110 that causes illumination source 110 to adjust the spectral range of wavelengths emitted from illumination source 110.

In some examples, the derivative based measurement engine 160 reads a file that contains the equations describing the shape and composition of the structure under measurement. In some examples, this file is generated by a lithography simulator such as PROLITH software available from KLA Corporation, Milpitas, California (USA). Based on this application information the derivative based measurement engine automatically sets the parameterization and constraints of the structural model.

Although the methods discussed herein are explained with reference to system 100, any optical or x-ray based metrology system configured to illuminate and detect light scattered from a specimen may be employed to implement the exemplary methods described herein. Furthermore, any electron based metrology system configured to illuminate a sample with one or more illumination beams of electrons and detect scattered electrons from a specimen may be employed to implement the exemplary methods described herein. Exemplary systems include an angle-resolved reflectometer (i.e., a beam profile reflectometer), an angle-resolved ellipsometer (i.e., beam profile ellipsometer), an angle-resolved reflectometer, a scatterometer, a spectroscopic reflectometer or ellipsometer, a spectroscopic reflectometer or ellipsometer with multiple angles of illumination, a Mueller Matrix spectroscopic ellipsomenter (e.g., a rotating compensator spectroscopic ellipsometer), a single wavelength ellipsometer, a single wavelength reflectometer, a RAMAN scatterometer, a transmission, small-angle x-ray scatterometer, a reflective, small-angle x-ray scatterometer, a grazing incidence, small-angle x-ray scatterometer, a transmission electron microscope, a scanning electron microscope, electron beam inspection systems, electron beam metrology systems, including multiple beam systems, etc.

By way of non-limiting example, an ellipsometer may include a single rotating compensator, multiple rotating compensators, a rotating polarizer, a rotating analyzer, a modulating element, multiple modulating elements, or no modulating element.

It is noted that the output from a source and/or target measurement system may be configured in such a way that the measurement system uses more than one technology. In fact, an application may be configured to employ any combination of available metrology sub-systems within a single tool, or across a number of different tools.

A system implementing the methods described herein may also be configured in a number of different ways. For example, a wide range of wavelengths (including visible, ultraviolet, and infrared), angles of incidence, states of polarization, and states of coherence may be contemplated. In another example, the system may include any of a number of different light sources (e.g., a directly coupled light source, a laser-sustained plasma light source, etc.). In another example, the system may include elements to condition light directed to or collected from the specimen (e.g., apodizers, filters, etc.).

In general, the optical dispersion properties of semiconductor structures under measurement may be approximated as isotropic. Under this assumption the material parameters are scalar values. Alternatively, the optical dispersion properties of semiconductor structures under measurement may be more accurately modelled as anisotropic. Under this assumption, the material parameters will be a matrix of different values, rather than a scalar value. Additional details regarding the treatment of anisotropic structures under measurement is described in U.S. Patent Publication No. 2018/0059019, the content of which is incorporated herein by reference in its entirety.

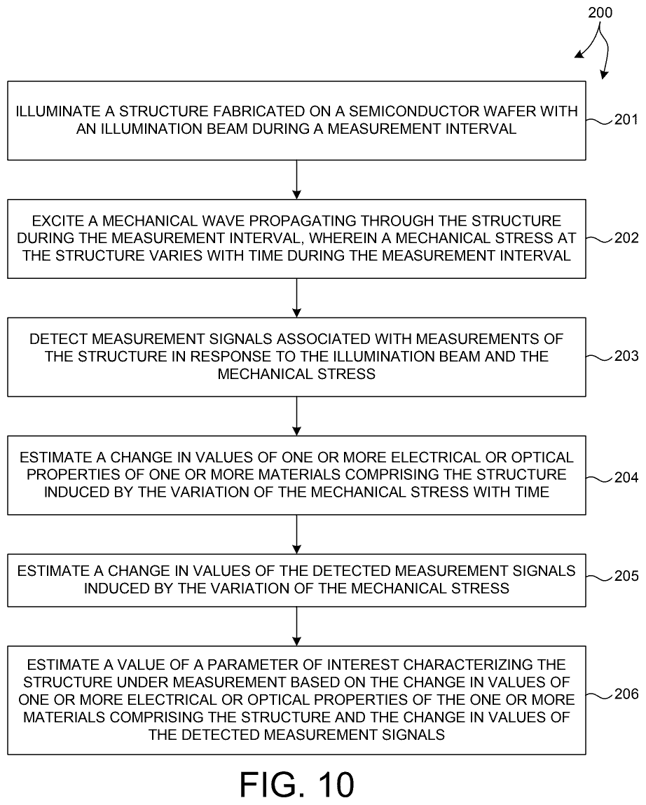

FIG. 10 illustrates a method 200 suitable for implementation by the metrology system 100 of the present invention. In one aspect, it is recognized that data processing blocks of method 200 may be carried out via a pre-programmed algorithm executed by one or more processors of computing system 130. While the following description is presented in the context of metrology system 100, it is recognized herein that the particular structural aspects of metrology system 100 do not represent limitations and should be interpreted as illustrative only.

In block 201, a structure fabricated on a semiconductor wafer is illuminated with an illumination beam during a measurement interval.

In block 202, a mechanical wave propagating through the structure is excited during the measurement interval. A mechanical stress at the structure varies with time during the measurement interval.

In block 203, measurement signals associated with measurements of the structure are detected in response to the illumination beam and the mechanical stress.

In block 204, a change in values of one or more electrical or optical properties of one or more materials comprising the structure is estimated. The change in values is induced by the variation of the mechanical stress with time.

In block 205, a change in values of the detected measurement signals induced by the variation of the mechanical stress is estimated.

In block 206, a value of a parameter of interest characterizing the structure under measurement is estimated based on the change in values of one or more electrical or optical properties of the one or more materials comprising the structure and the change in values of the detected measurement signals.

It should be recognized that the various steps described throughout the present disclosure may be carried out by a single computer system, or, alternatively, multiple computer systems. Moreover, different subsystems, such as the spectroscopic ellipsometer 105, may include a computer system suitable for carrying out at least a portion of the steps described herein. Therefore, the aforementioned description should not be interpreted as a limitation on the present invention but merely an illustration. Further, the one or more computing systems 130 may be configured to perform any other step(s) of any of the method embodiments described herein.

The computing system 130 may include, but is not limited to, a cloud based computing system, a personal computer system, mainframe computer system, workstation, image computer, parallel processor, or any other computing device known in the art. In general, the term “computing system” may be broadly defined to encompass any device having one or more processors, which execute instructions from a memory medium. In general, computing system 130 may be integrated with a measurement system such as measurement system 100, or alternatively, may be separate from any measurement system. In this sense, computing system 130 may be remotely located and receive measurement data and user input from any measurement source and user input source, respectively.

Program instructions 134 implementing methods such as those described herein may be transmitted over or stored on carrier medium. The carrier medium may be a transmission medium such as a wire, cable, or wireless transmission link. The carrier medium may also include a computer-readable medium such as a read-only memory, a random access memory, a magnetic or optical disk, or a magnetic tape. For example, as illustrated in FIG. 3, program instructions 134 stored in memory 132 are transmitted to processor 131 over bus 133. Program instructions 134 are stored in a computer readable medium (e.g., memory 132). Exemplary computer-readable media include read-only memory, a random access memory, a magnetic or optical disk, or a magnetic tape.

As described herein, the term “critical dimension” includes any critical dimension of a structure (e.g., bottom critical dimension, middle critical dimension, top critical dimension, sidewall angle, grating height, trench depth, etc.), a critical dimension between any two or more structures (e.g., distance between two structures), a displacement between two or more structures (e.g., overlay displacement between overlaying grating structures, etc.), and a dispersion property value of a material used in the structure or part of the structure. Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect. However, such terms of art do not limit the scope of the term “metrology system” as described herein. The metrology system may be configured as a LED inspection tool, edge inspection tool, backside inspection tool, macro-inspection tool, or multi-mode inspection tool (involving data from one or more platforms simultaneously), and any other metrology or inspection tool.

Various embodiments are described herein for a semiconductor processing system (e.g., an inspection system or a lithography system) that may be used for processing a specimen. The term “specimen” is used herein to refer to a site, or sites, on a wafer, a reticle, or any other sample that may be processed (e.g., printed, measured, or inspected for defects) by means known in the art. In some examples, the specimen includes a single site having one or more measurement targets whose simultaneous, combined measurement is treated as a single specimen measurement or reference measurement. In some other examples, the specimen is an aggregation of sites where the measurement data associated with the aggregated measurement site is a statistical aggregation of data associated with each of the multiple sites. Moreover, each of these multiple sites may include one or more measurement targets associated with a specimen or reference measurement.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO₂. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A metrology system comprising:
an illumination subsystem configured to illuminate a structure fabricated on a semiconductor specimen with an illumination beam during a measurement interval;
a mechanical wave excitation source configured to excite a mechanical wave propagating through the structure during the measurement interval, wherein a mechanical stress at the structure varies with time during the measurement interval;
a detector configured to detect measurement signals associated with measurements of the structure in response to the illumination beam and the amount of mechanical stress; and
a computing system configured to:
estimate a change in values of one or more electrical or optical properties of one or more materials comprising the structure induced by the variation of the mechanical stress;
estimate a change in values of the detected measurement signals induced by the variation of the mechanical stress; and
estimate a value of a parameter of interest characterizing the structure under measurement based on the change in values of one or more electrical or optical properties of the one or more materials comprising the structure and the change in values of the detected measurement signals.

2. The metrology system of claim 1, wherein the estimating of the value of a parameter of interest involves a trained derivative based measurement model.

3. The metrology system of claim 2, wherein the parameter of interest is any of an optical, electrical, mechanical, or thermal property of a material, a critical dimension, or a film thickness.

4. The metrology system of claim 1, wherein the mechanical wave excitation source is an ultrasonic actuator having a selectable frequency and selectable amplitude output.

5. The metrology system of claim 1, wherein the structure under measurement includes a plurality of different materials.

6. The metrology system of claim 1, wherein the metrology system is an optically based metrology system, an electron based metrology system, or an x-ray based metrology system.

7. The metrology system of claim 1, wherein the estimating of the change in values of one or more electrical or optical properties of a material of the one or more materials comprising the structure involves a measurement of a change in value of the one or more electrical or optical properties of a metrology target induced by the variation of the mechanical stress, wherein the metrology target is disposed on the semiconductor specimen at a location different from a location of the structure under measurement, and wherein the metrology target includes a single film layer of the material.

8. The metrology system of claim 1, wherein the mechanical wave excitation source is in physical contact with a backside of the semiconductor specimen.

9. The metrology system of claim 1, wherein the mechanical wave excitation source is not in contact with a surface of the semiconductor specimen, and wherein the mechanical wave excitation source generates a pressure wave that excites the mechanical wave propagating through the structure during the measurement interval.

10. The metrology system of claim 1, wherein the detected measurement signals are values of one or more Mueller matrix elements, values of one or more harmonic signals, or values of one or more detected image signals.

11. The metrology system of claim 1, wherein the illumination beam is incident on the semiconductor specimen over a measurement spot, and wherein the mechanical wave fully overlaps the illumination beam over the measurement spot or partially overlaps the illumination beam over the measurement spot.

12. The metrology system of claim 11, wherein an excitation intensity of the mechanical wave is controlled in proportion to an intensity of the illumination beam based on the structure under measurement.

13. The metrology system of claim 1, wherein the illumination beam is incident on the semiconductor specimen over a measurement spot, wherein the mechanical wave is incident on the semiconductor wafer over an acoustic wave spot, and wherein a size of the acoustic wave spot is larger than a size of the measurement spot.

14. The metrology system of claim 1, wherein the illumination beam includes a beam of photons incident on the sample or a beam of electrons incident on the sample.

15. A method comprising:
illuminating a structure fabricated on a semiconductor specimen with an illumination beam during a measurement interval;
exciting a mechanical wave propagating through the structure during the measurement interval, wherein a mechanical stress at the structure varies with time during the measurement interval;
detecting measurement signals associated with measurements of the structure in response to the illumination beam and the mechanical stress;
estimating a change in values of one or more electrical or optical properties of one or more materials comprising the structure induced by the variation of the mechanical stress with time;
estimating a change in values of the detected measurement signals induced by the variation of the mechanical stress; and
estimating a value of a parameter of interest characterizing the structure under measurement based on the change in values of one or more electrical or optical properties of the one or more materials comprising the structure and the change in values of the detected measurement signals.

16. The method of claim 15, wherein the detected measurement signals are associated with measurements of the structure at multiple wavelengths, multiple angles of incidence, multiple azimuth angles, or any combination thereof.

17. The method of claim 15, wherein the structure under measurement includes a plurality of different materials.

18. The method of claim 15, wherein the estimating of the change in values of one or more electrical or optical properties of a material of the one or more materials comprising the structure involves a measurement of a change in value of the one or more electrical or optical properties of a metrology target induced by the variation of the mechanical stress with time, wherein the metrology target is disposed on the semiconductor specimen at a location different from a location of the structure under measurement, and wherein the metrology target includes a single film layer of the material.

19. The method of claim 15, wherein the variation of the mechanical stress is periodic or non-periodic.

20. A metrology system comprising:
an illumination subsystem configured to illuminate a structure fabricated on a semiconductor specimen with an illumination beam during a measurement interval;
a mechanical wave excitation source configured to excite a mechanical wave propagating through the structure during the measurement interval, wherein a mechanical stress at the structure varies with time during the measurement interval;
a detector configured to detect measurement signals associated with measurements of the structure in response to the illumination beam and the amount of mechanical stress; and
a non-transitory, computer-readable medium storing instructions that, when executed by one or more processors, causes the one or more processors to:
estimate a change in values of one or more electrical or optical properties of one or more materials comprising the structure induced by the variation of the mechanical stress;
estimate a change in values of the detected measurement signals induced by the variation of the mechanical stress; and
estimate a value of a parameter of interest characterizing the structure under measurement based on the change in values of one or more electrical or optical properties of the one or more materials comprising the structure and the change in values of the detected measurement signals.
